(19) United States
(12) Patent Application Publication
(10) Pub. No.: US 2024/0038616 A1
(43) Pub. Date: Feb. 1, 2024

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Cheng-Chieh Li, Hsinchu City (TW); Chih-Wei Wu, Yilan County (TW); Ying-Ching Shih, Hsinchu City (TW); Wen-Chih Chiou, Miaoli County (TW)

(73) Assignee: Taiwan Semiconductor Manufacturing Company, Ltd., Hsinchu (TW)

(21) Appl. No.: 17/873,170

(22) Filed: Jul. 26, 2022

(51) Int. Cl. H01L 23/367; H01L 25/065; H01L 23/00; H01L 21/56; H01L 23/31; H01L 23/373

(52) U.S. Cl. CPC H01L 23/367; H01L 25/0655; H01L 24/08; H01L 24/80; H01L 24/96; H01L 24/97; H01L 21/565; H01L 21/561; H01L 23/3128; H01L 23/3135; H01L 23/3736; H01L 2924/37001; H01L 2924/182; H01L 2224/08225; H01L 2224/80896; H01L 2224/80895; H01L 2924/15311

(57) ABSTRACT

Disclosed are a semiconductor package and a manufacturing method of a semiconductor package. In one embodiment, the semiconductor package includes an interposer substrate, a plurality of semiconductor dies, a first encapsulant, at least one heat dissipation element and a second encapsulant. The plurality of semiconductor dies are disposed on the interposer substrate. The first encapsulant is disposed on the interposer substrate and surrounds the plurality of semiconductor dies. The at least one heat dissipation element is disposed on the plurality of semiconductor dies. The second encapsulant is disposed on the first encapsulant and surrounds the at least one heat dissipation element.

### BACKGROUND

A typical problem with miniaturization of semiconductor devices is heat dissipation during operation. A prolonged exposure of a die by operating at excessive temperatures may decrease the reliability and lifetime of the die. As such, improvements to heat transfer are still needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A through FIG. 1H schematically illustrate a process flow for manufacturing a semiconductor package in accordance with some embodiments of the present disclosure.

FIG. 2A through FIG. 2H schematically illustrate a process flow for manufacturing another semiconductor package in accordance with some alternative embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For structural support and/or heat dissipation purposes, a silicon bulk is bonded to rear surfaces of semiconductor dies through a transient liquid phase (TLP) bonding method, in which a metal layer and a solder layer are formed between the silicon bulk and the semiconductor dies to facilitate the bonding between the silicon bulk and the semiconductor dies. However, soldering void defects are prone to be generated when rear surfaces of the semiconductor dies are not level with each other. In addition, a singulation process becomes difficult or even impossible when the solder layer and/or the metal layer is thick. Moreover, the silicon bulk is less efficient in heat dissipation than a metal bulk.

The present disclosure is related to a semiconductor package and a manufacturing method thereof. In some embodiments, one or more heat dissipation elements (e.g., metal bulks) with high thermal conductivity is/are bonded to semiconductor dies to improve heat dissipation efficiency. The one or more heat dissipation elements of appropriate dimensions (e.g., length, width, or thickness) can be selected according to the needs to improve design flexibility of the semiconductor package. More than one heat dissipation elements can be bonded to the semiconductor dies to reduce the bonding area between each heat dissipation element and corresponding semiconductor die(s), thereby reducing the defects and/or improving bond quality. When a singulation process is needed, the one or more heat dissipation elements are disposed in regions not traversed by the scribe lines, and regions traversed by the scribe lines are disposed with an encapsulant that is easier to cut than the one or more heat dissipation elements to facilitate the singulation process and/or to improve integrated yield. In some embodiments, a solder layer and/or a metal layer are disposed to bond the one or more heat dissipation elements to the semiconductor dies, and the solder layer and/or the metal layer may be formed in regions not traversed by the scribe lines to facilitate the singulation process.

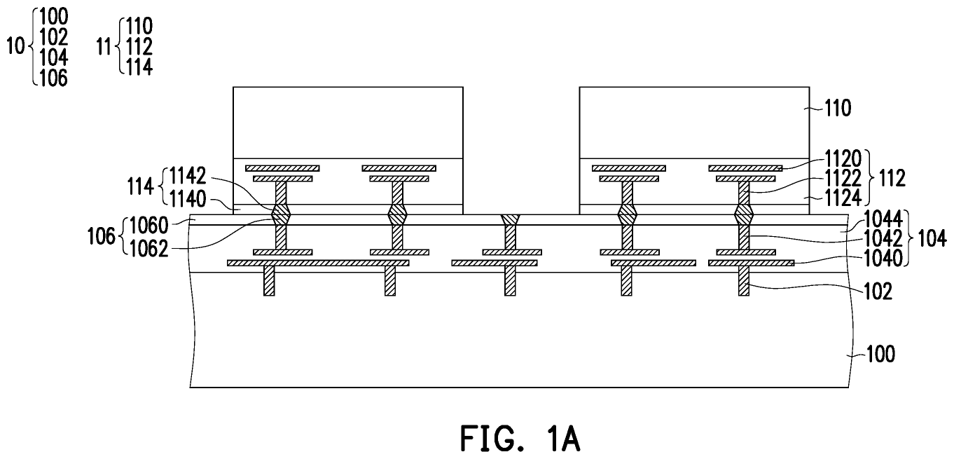

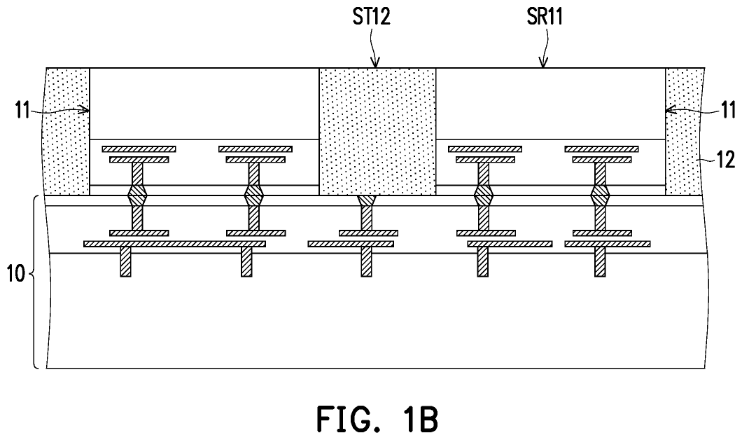

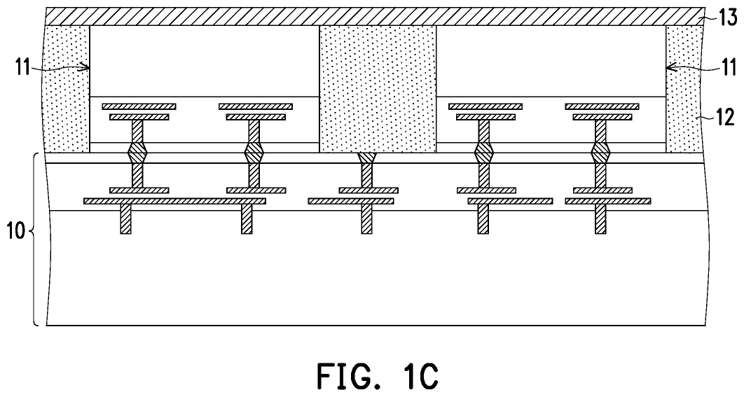

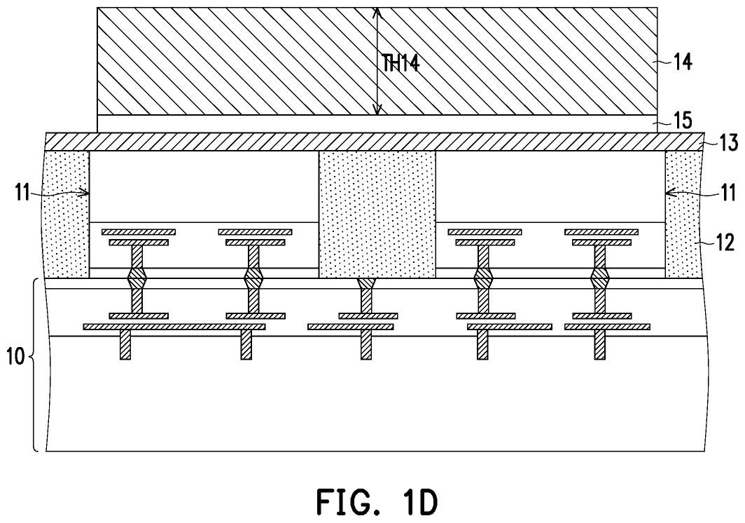

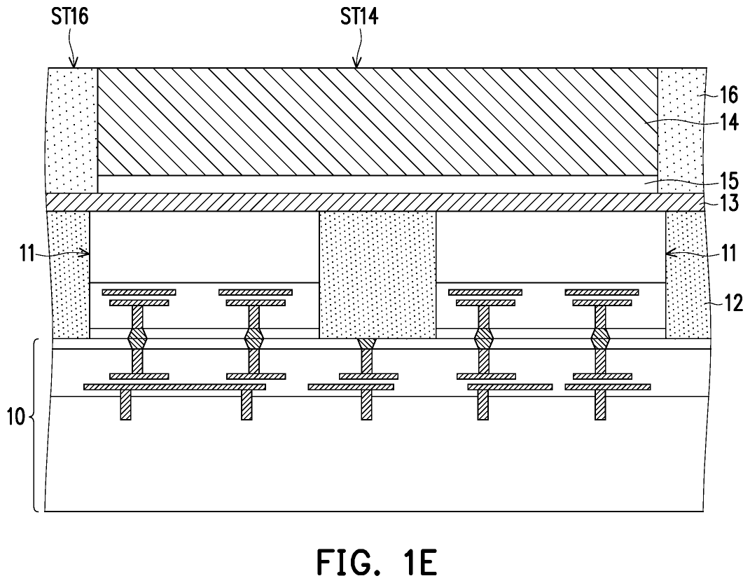

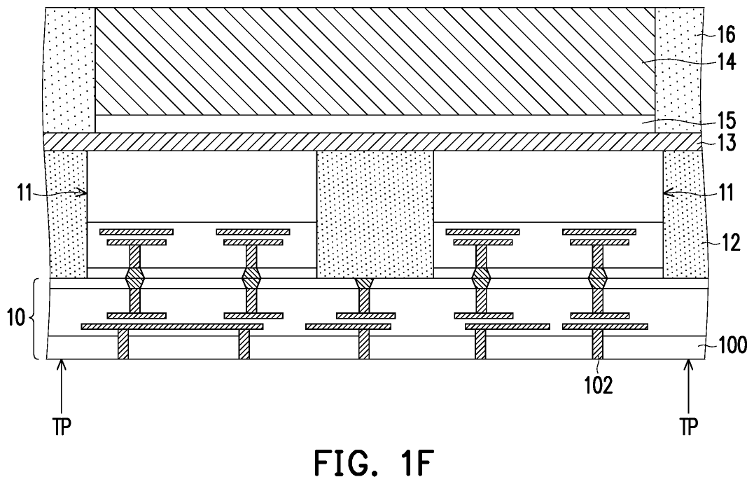

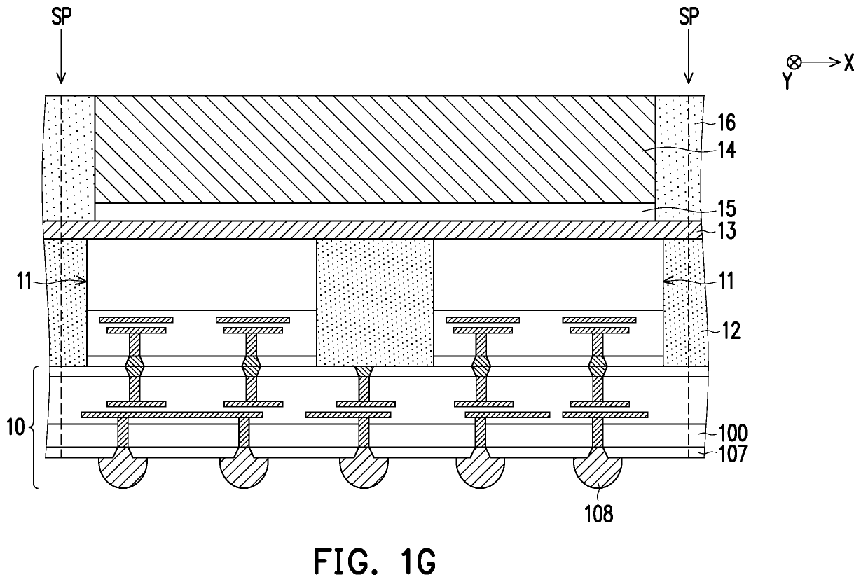

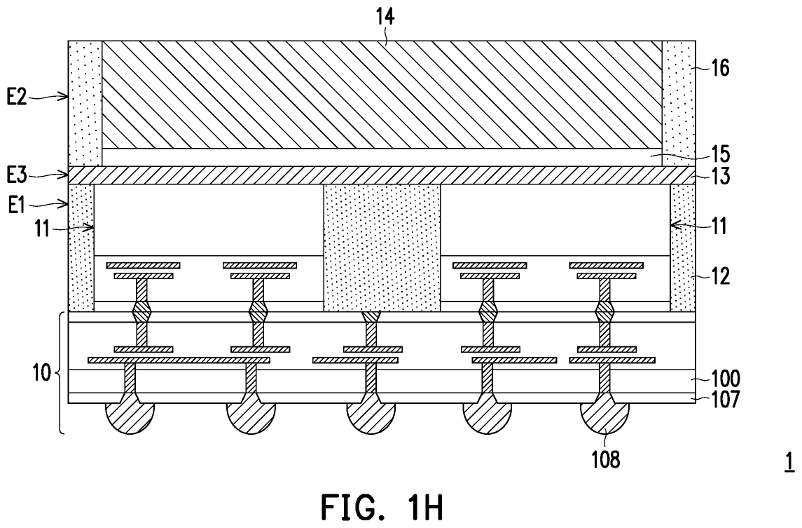

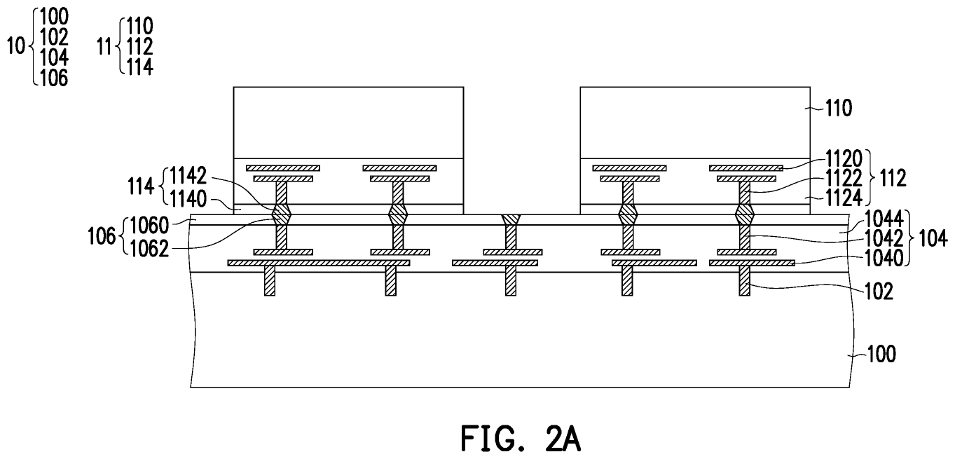

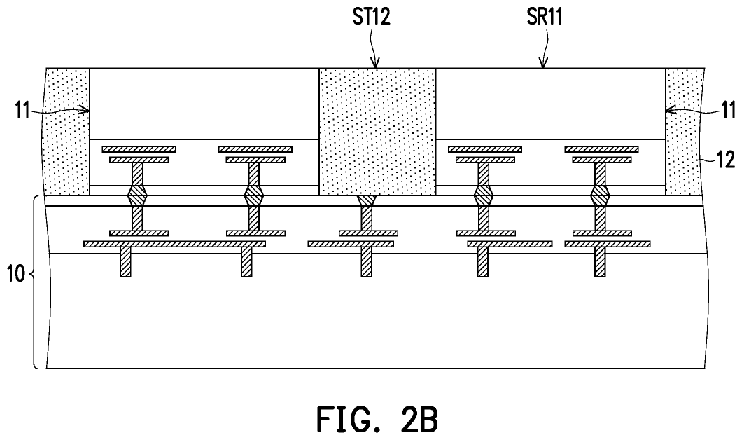

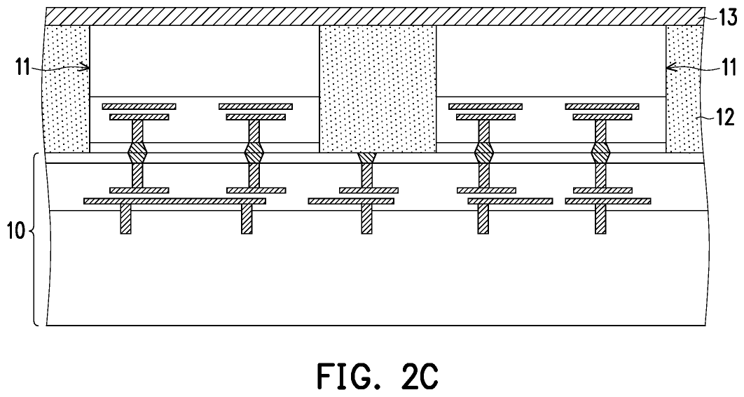

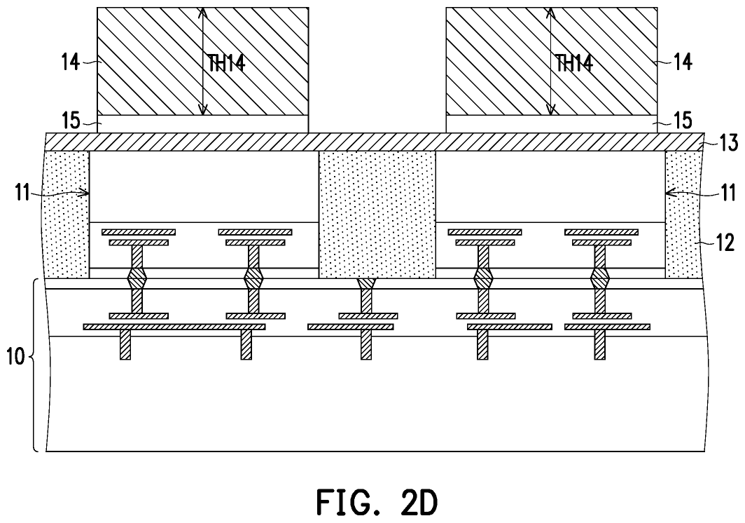

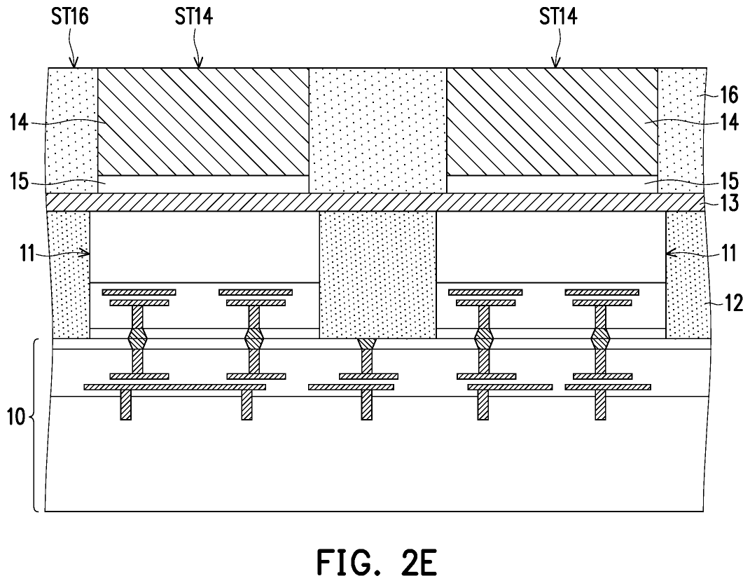

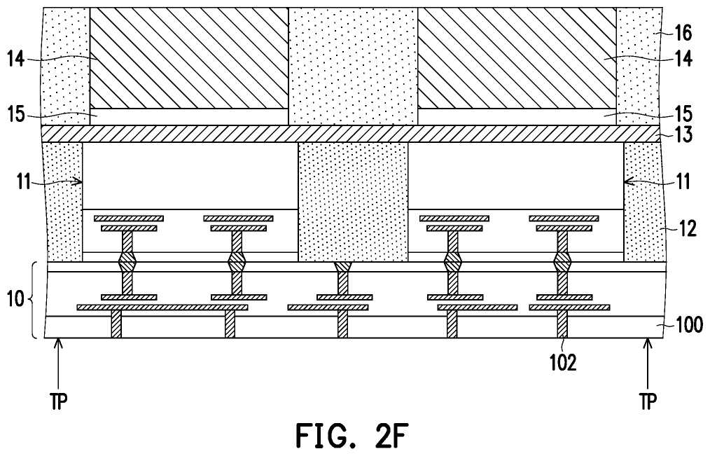

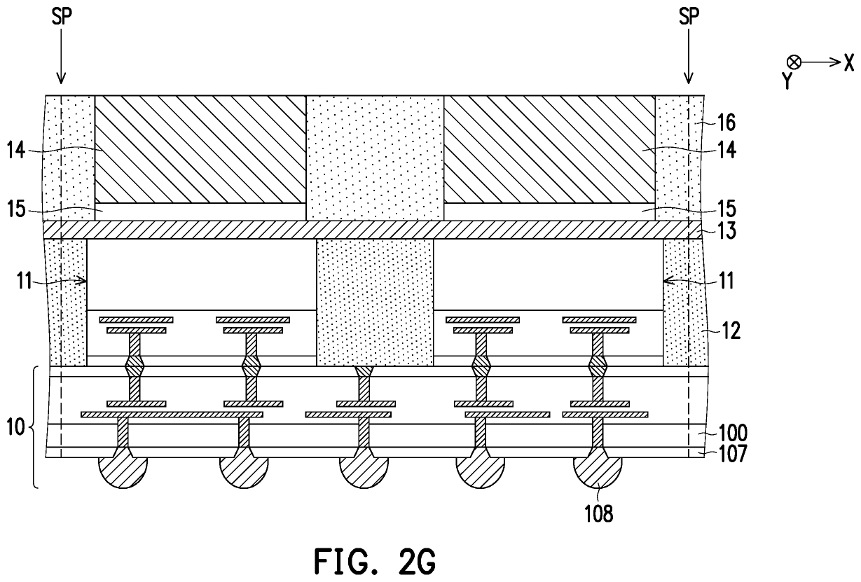

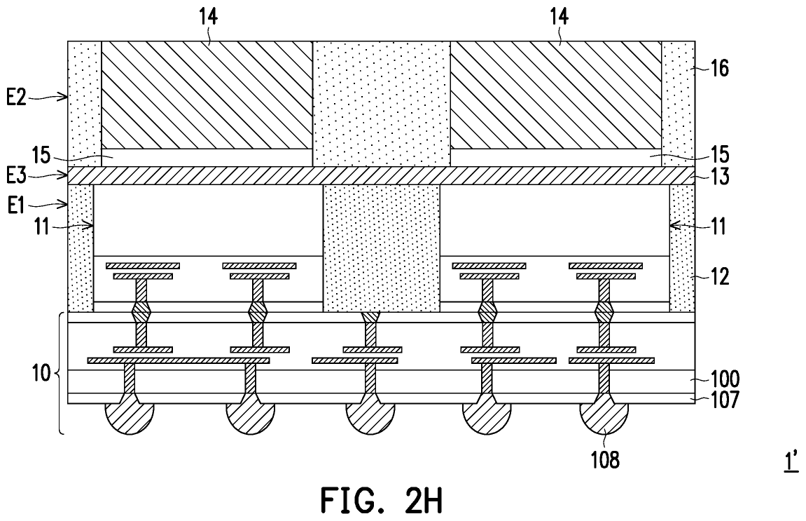

FIG. 1A through FIG. 1H schematically illustrate a process flow for manufacturing a semiconductor package in accordance with some embodiments of the present disclosure. FIG. 2A through FIG. 2H schematically illustrate a process flow for manufacturing another semiconductor package in accordance with some alternative embodiments of the present disclosure.

Referring to FIG. 1A through FIG. 1H, a manufacturing method of a semiconductor package 1 in accordance with some embodiments of the present disclosure is provided. Referring to FIG. 1A, the manufacturing method may include bonding a plurality of semiconductor dies 11 on an interposer substrate 10.

The interposer substrate 10 may be a silicon interposer or an organic interposer, but not limited thereto. In some embodiments, the interposer substrate 10 includes a semiconductor substrate 100, through substrate vias 102, an interconnect structure 104, and a bonding structure 106, but not limited thereto.

The semiconductor substrate 100 may be or includes a monocrystalline semiconductor substrate such as a silicon substrate, a silicon-on-insulator (SOI) substrate, silicon-germanium on insulator (SGOI) or a germanium-on-insulator (GOI) substrate. In some embodiments, the semiconductor substrate 100 is made of semiconductor materials, such as semiconductor materials of the groups III-V of the periodic table. In some embodiments, the semiconductor substrate 100 includes elementary semiconductor materials such as silicon or germanium, compound semiconductor materials such as silicon carbide, gallium arsenide, indium arsenide, or indium phosphide or alloy semiconductor materials such as silicon germanium, silicon germanium carbide, gallium arsenide phosphide, or gallium indium phosphide. In some embodiments, although not shown, the semiconductor substrate 100 further include active or passive devices, such as transistors, capacitors, resistors, or diodes formed therein.

The through substrate vias 102 are formed by forming holes or recesses in the semiconductor substrate 100 and then filling the recesses with a conductive material. In some embodiments, the recesses are formed by, for example, etching, milling, laser drilling or the like. In some embodiments, the conductive material is formed by an electro-chemical plating process, chemical vapor deposition (CVD), atomic layer deposition (ALD) or physical vapor deposition (PVD), and the conductive material may include copper, tungsten, aluminum, silver, gold or a combination thereof.

The interconnect structure 104 overlies the semiconductor substrate 100 and is electrically coupled between the through substrate vias 102 and the bonding structure 106. The interconnect structure 104 may include a plurality of wires 1040, a plurality of vias 1042 and a dielectric layer 1044. Although not shown, the plurality of wires 1040 and the plurality of vias 1042 may be alternatingly stacked in the dielectric layer 1044, but not limited thereto. In some embodiments, the material of the plurality of wires 1040 and the plurality of vias 1042 includes copper or copper alloys. In some embodiments, the material of the dielectric layer 1044 includes silicon oxide, silicon nitride, undoped silicate glass material or a suitable dielectric material.

The bonding structure 106 overlies the interconnect structure 104. The bonding structure 106 may include a bonding dielectric layer 1060 and bonding conductors 1062. The bonding dielectric layer 1060 may include a plurality of contact openings, and the bonding conductors 1062 are exposed by the contact openings of the bonding dielectric layer 1060. In some embodiments, the bonding dielectric layer 1060 is formed through performing a chemical vapor deposition (CVD) process such as low-pressure CVD (LPCVD), plasma enhanced CVD (PECVD), and high-density plasma CVD (HDPCVD), and the material of the bonding dielectric layer 1060 includes silicon oxide, silicon nitride, undoped silicate glass material or a suitable dielectric material. In some embodiments, the bonding conductors 1062 is formed through performing deposition, plating, or other suitable processes, and the material of the bonding conductors 1062 includes aluminum, copper, alloys thereof or other suitable metallic material. In some embodiments, top surfaces of the bonding conductors 1062 are substantially level with a top surface of the bonding dielectric layer 1060.

The plurality of semiconductor dies 11 are individual dies singulated from the same wafer or different wafers. In some embodiments, the plurality of semiconductor dies 11 contain the same circuitry, such as devices and metallization patterns, or the plurality of semiconductor dies 11 are the same type of dies. In some alternative embodiments, the plurality of semiconductor dies 11 have different circuitry or are different types of dies.

The plurality of semiconductor dies 11 may include memory, flash, power chip, power module, converter, sensor, logic die and so on that can work in conjunction with other semiconductor elements in order to provide a desired functionality to the user. In some embodiments, the plurality of semiconductor dies 11 include digital dies, analog dies, mixed signal dies, such as application-specific integrated circuit (ASIC) dies, logic dies, sensor dies, other kinds of integrated circuit dies or a combination of the above, but is not limited thereto.

In some embodiments, each of the plurality of semiconductor dies 11 includes a semiconductor substrate 110, an interconnection structure 112 and a bonding structure 114, but not limited thereto.

The semiconductor substrate 110 may be or includes a monocrystalline semiconductor substrate such as a silicon substrate, a silicon-on-insulator (SOI) substrate, silicon-germanium on insulator (SGOI) or a germanium-on-insulator (GOI) substrate. In some embodiments, the semiconductor substrate 110 is made of semiconductor materials, such as semiconductor materials of the groups III-V of the periodic table. In some embodiments, the semiconductor substrate 110 includes elementary semiconductor materials such as silicon or germanium, compound semiconductor materials such as silicon carbide, gallium arsenide, indium arsenide, or indium phosphide or alloy semiconductor materials such as silicon germanium, silicon germanium carbide, gallium arsenide phosphide, or gallium indium phosphide. In some embodiments, although not shown, the semiconductor substrate 110 further include active or passive devices, such as transistors, capacitors, resistors, or diodes formed therein.

The interconnection structure 112 overlies the semiconductor substrate 110 and is electrically coupled to the bonding structure 114. The interconnect structure 112 may include a plurality of wires 1120, a plurality of vias 1122 and a dielectric layer 1124. Although not shown, the plurality of wires 1120 and the plurality of vias 1122 may be alternatingly stacked in the dielectric layer 1124, but not limited thereto. In some embodiments, the material of the plurality of wires 1120 and the plurality of vias 1122 includes copper or copper alloys. In some embodiments, the material of the dielectric layer 1124 includes silicon oxide, silicon nitride, undoped silicate glass material or a suitable dielectric material.

The bonding structure 114 overlies the interconnect structure 112. The bonding structure 114 may include a bonding dielectric layer 1140 and bonding conductors 1142. The bonding dielectric layer 1140 may include a plurality of contact openings, and the bonding conductors 1142 are exposed by the contact openings of the bonding dielectric layer 1140. In some embodiments, the bonding dielectric layer 1140 is formed through performing a chemical vapor deposition (CVD) process such as low-pressure CVD (LPCVD), plasma enhanced CVD (PECVD), and high-density plasma CVD (HDPCVD), and the material of the bonding dielectric layer 1140 includes silicon oxide, silicon nitride, undoped silicate glass material or a suitable dielectric material. In some embodiments, the bonding conductors 1142 is formed through performing deposition, plating, or other suitable processes, and the material of the bonding conductors 1142 includes aluminum, copper, alloys thereof or other suitable metallic material. In some embodiments, top surfaces of the bonding conductors 1142 are substantially level with a top surface of the bonding dielectric layer 1140.

In the embodiments of the disclosure, the surface where the bonding conductors 1142 are distributed on may be referred to as an active surface of the semiconductor die, and the surface opposite to the active surface of the semiconductor die may be referred to as a rear surface of the semiconductor die.

The plurality of semiconductor dies 11 may be placed onto the interposer substrate 10 through a pick-and-place method, in which active surfaces of the semiconductor dies 11 face the interposer substrate 10. Even though two semiconductor dies 11 are presented in FIG. 1A for illustrative purposes, it is understood that more than two semiconductor dies 11 can be provided on the interposer substrate 10.

In some embodiments, a bonding process is performed to bond the plurality of semiconductor dies 11 to the interposer substrate 10, wherein the bonding conductors 1062 and the bonding conductors 1142 are bonded to each other via metal-to-metal bonding, and the bonding dielectric layer 1060 and the bonding dielectric layer 1140 are bonded to each other via dielectric-to-dielectric fusion bonding. In some alternative embodiments, although not shown, the plurality of semiconductor dies 11 are bonded to the interposer substrate 10 using conductive connectors such as metal pillars, micro bumps or combinations thereof, and an underfill may be provided by capillary underfill filling (CUF) to fill the interstices between the interposer substrate 10 and the plurality of semiconductor dies 11 so as to protect the conductive connectors against thermal or physical stresses.

Referring to FIG. 1B, the manufacturing method may further include forming a first encapsulant 12 on the interposer substrate 10 and surrounding the plurality of semiconductor dies 11. In some embodiments, the first encapsulant 12 is formed by a molding process (e.g., an over-molding process or a compression molding process) followed by a planarization process.

For example, an encapsulation material (not shown) is formed over the interposer substrate 10 to at least encapsulate the plurality of semiconductor dies 11. In some embodiments, the plurality of semiconductor dies 11 are fully covered and not revealed by the encapsulation material. In some embodiments, the encapsulation material may be a molding compound, a molding underfill, a resin (such as an epoxy resin), or the like. The encapsulation material is then partially removed by the planarization process until the rear surfaces SR11 of the semiconductor dies 11 are exposed. In some embodiments, upper portions of the plurality of semiconductor dies 11 may be removed during the planarization process. Planarization of the encapsulation material may produce an encapsulant (first encapsulant 12) that surrounds the plurality of semiconductor dies 11, but rear surfaces SR11 of the plurality of semiconductor dies 11 are exposed from the encapsulant (first encapsulant 12). In some embodiments, the planarization of the encapsulation material includes performing a mechanical grinding process and/or a chemical mechanical polishing (CMP) process. After the grinding process or the polishing process, rear surfaces SR11 of the plurality of semiconductor dies 11 may be substantially coplanar or level with a top surface ST12 of the first encapsulant 12.

The manufacturing method may further include bonding at least one heat dissipation element 14 on the plurality of semiconductor dies 11 after the first encapsulant 12 is formed (referring to FIG. 1D). In some embodiments, as shown in FIG. 1C, the manufacturing method may further include forming a backside metal layer (may also called a seed layer) 13 on the plurality of semiconductor dies 11 and the first encapsulant 12 before bonding the at least one heat dissipation element 14 on the plurality of semiconductor dies 11 for better adhesion and connection reliability.

Referring to FIG. 1C, the backside metal layer 13 may be in contact with and cover the plurality of semiconductor dies 11 and the first encapsulant 12. In some embodiments, the backside metal layer 13 is a single layer or a multi-layered structure. In some embodiments, the backside metal layer 13 is formed by a sputtering process, a physical vapor deposition (PVD) process, a plating process, or the like, and the material of the backside metal layer 13 includes copper, tantalum, titanium-copper alloys, or other suitable metallic materials.

Referring to FIG. 1D, the manufacturing method may further include bonding at least one heat dissipation element 14 on the plurality of semiconductor dies 11. Even though only one heat dissipation element 14 is presented in FIG. 1D for illustrative purposes, it is understood that more than one heat dissipation elements 14 can be provided on the plurality of semiconductor dies 11.

The heat dissipation element 14 has high thermal conductivity, for example, higher than about 5 W/k*m, but not limited thereto. In some embodiments, the heat dissipation element 14 is a metal bulk. In some embodiments, a material of the at least one heat dissipation element 14 includes metal, metal alloy or a combination thereof. For example, the material of the at least one heat dissipation element 14 includes gold, silver, copper, aluminum, magnesium, tungsten, molybdenum, other metal material or alloys of the above, but not limited thereto. The one or more heat dissipation elements 14 of appropriate dimensions (e.g., length, width, or thickness) can be selected according to the needs to improve design flexibility of the semiconductor package. In some embodiments, a thickness TH14 of the at least one heat dissipation element 14 is 50 μm to 500 μm.

In some embodiments, bonding the at least one heat dissipation element 14 on the plurality of semiconductor dies 11 may include bonding the at least one heat dissipation element 14 on the backside metal layer 13 through a solder layer 15. For example, the solder layer 15 may be formed on the heat dissipation element 14 prior to bonding the heat dissipation element 14 on the plurality of semiconductor dies 11. The heat dissipation element 14 with the solder layer 15 is placed on the backside metal layer 13 through a pick-and-place method, in which the solder layer 15 faces the backside metal layer 13. Then, a reflow process, a thermo compression bonding (TCB) process or a transient liquid phase (TLP) bonding process is performed to fix the heat dissipation element 14 on the plurality of semiconductor dies 11.

In some embodiments, the solder layer 15 fully covers the surface of the heat dissipation element 14 that faces the backside metal layer 13, namely, an area of the solder layer 15 may be equal to the area of the heat dissipation element 14. In some embodiments, the area of the heat dissipation element 14 is smaller than an area of the backside metal layer 13, namely, a portion of the backside metal layer 13 is not covered by or overlapped with the heat dissipation element 14. In some embodiments, the heat dissipation element 14 is disposed corresponding to one or more semiconductor dies 11 among the plurality of semiconductor dies 11, namely, the heat dissipation element 14 at least partially overlaps one or more semiconductor dies 11 among the plurality of semiconductor dies 11. By disposing the heat dissipation element 14 corresponding to one or more semiconductor dies 11, the heat generated by the one or more semiconductor dies 11 during operation can be discharged more efficiently. For example, the heat dissipation element 14 may overlap two or more adjacent semiconductor dies 11 and the first encapsulant 12 located between the two or more adjacent semiconductor dies 11; however, the number of the semiconductor dies 11 overlapped with the heat dissipation element 14 is not limited thereto.

In some alternative embodiments, the backside metal layer 13 is a patterned layer, and the area of the backside metal layer 13 may be equal to the area of the heat dissipation element 14. For example, the backside metal layer 13 exposed by the heat dissipation element 14 and the solder layer 15 may be removed by using lithography and etching process, whereby a photoresist is deposited and patterned and then used as a mask during an etching process in order to remove the backside metal layer 13 exposed by the heat dissipation element 14 and the solder layer 15.

Referring to FIG. 1E, the manufacturing method may further include forming a second encapsulant 16 on the first encapsulant 12, wherein the second encapsulant 16 surrounds the at least one heat dissipation element 14 and overlaps the first encapsulant 12. In some embodiments, the second encapsulant 16 is formed by a molding process (e.g., an over-molding process or a compression molding process) followed by a planarization process.

For example, an encapsulation material (not shown) is formed over the backside metal layer 13 to at least encapsulate the at least one heat dissipation element 14. In some embodiments, the at least one heat dissipation element 14 is fully covered and not revealed by the encapsulation material. In some embodiments, the encapsulation material may be a molding compound, a molding underfill, a resin (such as an epoxy resin), or the like. The encapsulation material is then partially removed by the planarization process until the top surface ST14 of the at least one heat dissipation element 14 is exposed. In some embodiments, upper portions of the at least one heat dissipation element 14 may be removed during the planarization process. Planarization of the encapsulation material may produce an encapsulant (second encapsulant 16) that surrounds the at least one heat dissipation element 14, but the top surface ST14 of the at least one heat dissipation element 14 is exposed from the encapsulant (second encapsulant 16). In some embodiments, the planarization of the encapsulation material includes performing a mechanical grinding process and/or a chemical mechanical polishing (CMP) process. After the grinding process or the polishing process, the top surface ST14 of the at least one heat dissipation element 14 may be substantially coplanar or level with a top surface ST16 of the second encapsulant 16.

The manufacturing method may further include performing a singulation process SP after the second encapsulant 16 is formed (referring to FIG. 1G). In some embodiments, as shown in FIG. 1F, the manufacturing method may further include a thinning process TP before the singulation process SP to partially remove or thin the semiconductor substrate 100 of the interposer substrate 10 until the through substrate vias 102 located in the semiconductor substrate 100 are exposed. In some embodiments, the thinning process may include a back-grinding process, a polishing process or an etching process. In some embodiments, after the thinning process TP, the thickness of the interposer substrate 100 is reduced.

Referring to FIG. 1G, a dielectric layer 107 and conductive terminals 108 are sequentially formed on the thinned semiconductor substrate 100. The dielectric layer 107 may include a plurality of contact openings, and the conductive terminals 108 are exposed by the contact openings of the dielectric layer 107. In some embodiments, the dielectric layer 107 is formed through performing a chemical vapor deposition (CVD) process such as low-pressure CVD (LPCVD), plasma enhanced CVD (PECVD), and high-density plasma CVD (HDPCVD), and the material of the dielectric layer 107 includes silicon oxide, silicon nitride, undoped silicate glass material or a suitable dielectric material. In some embodiments, the conductive terminals 108 are formed in the contact openings of the dielectric layer 107 through a ball placement process, and the conductive terminals 108 include lead-free solder balls, solder balls, ball grid array (BGA) balls, bumps, C4 bumps or micro bumps.

After the conductive terminals 108 are formed, a singulation process SP may be selectively performed to cut the second encapsulant 16, the first encapsulant 12, the interposer substrate 10 and the backside metal layer 13 (if existed). For example, the semiconductor structure shown in FIG. 1G is attached to a tape frame (not shown) which holds the semiconductor structure in place during the singulation process. Subsequently, a cutting or singulation process may be performed on the semiconductor structure. For example, a mechanical saw, laser saw, or other suitable tool is used to cut across the semiconductor structure along scribe lines (refer to the dash lines in FIG. 1G; e.g., a series of cross lines along directions X and Y), so that several semiconductor packages (FIG. 1H schematically illustrates a semiconductor package 1) are separated, or singulated, from each other.

The efficiency of the singulation process SP can be improved and/or the lifetime of the tools used in the singulation process SP cab be prolonged by placing elements or layers (such as metal layers) that are difficult to cut outside the scribe lines. For example, the one or more heat dissipation elements 14 and the solder layer 15 are disposed in regions not traversed by the scribe lines (e.g., the heat dissipation elements 14 and the solder layer 15 are located between two adjacent scribe lines) to facilitate the singulation process SP and/or to improve integrated yield. In some alternative embodiments, although not shown, the backside metal layer 13 exposed by the heat dissipation element 14 and the solder layer 15 may be removed, and the space occupied by the removed backside metal layer 13 may be disposed with the second encapsulant 16.

Referring to FIG. 1H, the semiconductor package 1 includes the interposer substrate 10, the plurality of semiconductor dies 11, the first encapsulant 12, the heat dissipation element 14 (e.g., a metal bulk), and the second encapsulant 16. The plurality of semiconductor dies 11 are disposed on the interposer substrate 10. The first encapsulant 12 is disposed on the interposer substrate 10 and surrounds the plurality of semiconductor dies 11. The heat dissipation element 14 is disposed on the plurality of semiconductor dies 11. The second encapsulant 16 is disposed on the first encapsulant 12 and surrounds the heat dissipation element 14, wherein an outer edge E2 of the second encapsulant 16 is aligned with an outer edge E1 of the first encapsulant 12 as a result of the singulation process SP shown in FIG. 1G.

In some embodiments, the semiconductor package 1 further includes the backside metal layer 13 and the solder layer 15. The backside metal layer 13 is disposed between the plurality of semiconductor dies 11 and the heat dissipation element 14, and an edge E3 of the backside metal layer 13 is aligned with the outer edge E2 of the second encapsulant 16 and the outer edge E1 of the first encapsulant 12 as a result of the singulation process SP shown in FIG. 1G. The solder layer 15 is disposed between the backside metal layer 13 and the heat dissipation element 14.

Referring to FIG. 2A through FIG. 2H, a manufacturing method of a semiconductor package 1′ in accordance with some embodiments of the present disclosure is provided.

The steps shown in FIG. 2A through FIG. 2C are similar to the steps shown in FIG. 1A through FIG. 1C, so the detailed descriptions are not repeated for brevity.

Referring to FIG. 2D, more than one heat dissipation elements 14 are bonded on the plurality of semiconductor dies 11, and each heat dissipation element 14 is boned to a corresponding semiconductor die 11 through a corresponding solder layer 15, and thus more heat dissipation paths are generated. Even though two heat dissipation elements 14 are presented in FIG. 2D for illustrative purposes, it is understood that more than two heat dissipation elements 14 can be provided on the plurality of semiconductor dies 11. In addition, the relative disposition relationship between the heat dissipation elements 14 and the semiconductor dies 11 can be one-to-many, many-to-one or one-to-one. Even though the heat dissipation element 14 having smaller width than that of the corresponding semiconductor die 11 is presented in FIG. 2D for illustrative purposes, it is understood that the width of the heat dissipation elements 14 may be equal to, greater than, or less than that of the corresponding semiconductor die 11.

The steps shown in FIG. 2E through FIG. 2G are similar to the steps shown in FIG. 1E through FIG. 1G, so the detailed descriptions are not repeated for brevity.

Referring to FIG. 2H, the semiconductor package 1′ includes the interposer substrate 10, the plurality of semiconductor dies 11, the first encapsulant 12, the plurality of heat dissipation element 14 (e.g., metal bulks), and the second encapsulant 16. The plurality of semiconductor dies 11 are disposed on the interposer substrate 10. The first encapsulant 12 is disposed on the interposer substrate 10 and surrounds the plurality of semiconductor dies 11. The plurality of heat dissipation elements 14 are disposed on the plurality of semiconductor dies 11. The second encapsulant 16 is disposed on the first encapsulant 12 and surrounds the plurality of heat dissipation elements 14, wherein an outer edge E2 of the second encapsulant 16 is aligned with an outer edge E1 of the first encapsulant 12 as a result of the singulation process SP shown in FIG. 2G.

In some embodiments, the semiconductor package 1′ further includes the backside metal layer 13 and the solder layers 15. The backside metal layer 13 is disposed between the plurality of semiconductor dies 11 and the plurality of heat dissipation elements 14, and an edge E3 of the backside metal layer 13 is aligned with the outer edge E2 of the second encapsulant 16 and the outer edge E1 of the first encapsulant 12 as a result of the singulation process SP shown in FIG. 2G. Each solder layer 15 is disposed between the backside metal layer 13 and the corresponding heat dissipation element 14.

In some alternative embodiments, although not shown, the backside metal layer 13 exposed by the plurality of heat dissipation elements 14 and the solder layers 15 may be removed, and the space occupied by the removed backside metal layer 13 may be disposed with the second encapsulant 16.

Under a fixed-size semiconductor package, the bonding area between each heat dissipation element and corresponding semiconductor die(s) reduces as the number of the heat dissipation elements increases. With the reduction of the bonding area, the influence of flatness on the formation of soldering void defects can be reduced, thereby reducing the generation of defects and/or improving bond quality or integrated yield. In addition, since the singulation process can be performed on areas between any two adjacent heat dissipation elements, the increase in the number of heat dissipation elements helps to reduce the size of the singulated semiconductor package.

Based on the above discussions, it can be seen that the present disclosure offers various advantages. It is understood, however, that not all advantages are necessarily discussed herein, and other embodiments may offer different advantages, and that no particular advantage is required for all embodiments.

In accordance with some embodiments of the present disclosure, a semiconductor package includes an interposer substrate, a plurality of semiconductor dies, a first encapsulant, at least one heat dissipation element and a second encapsulant. The plurality of semiconductor dies are disposed on the interposer substrate. The first encapsulant is disposed on the interposer substrate and surrounds the plurality of semiconductor dies. The at least one heat dissipation element is disposed on the plurality of semiconductor dies. The second encapsulant is disposed on the first encapsulant and surrounds the at least one heat dissipation element. In some embodiments, the second encapsulant overlaps the first encapsulant. In some embodiments, the number of the at least one heat dissipation element is one or more, and each heat dissipation element covers one or more semiconductor dies among the plurality of semiconductor dies. In some embodiments, rear surfaces of the plurality of semiconductor dies are level with a top surface of the first encapsulant. In some embodiments, a material of the at least one heat dissipation element comprises metal, metal alloy or a combination thereof. In some embodiments, the semiconductor package further includes a backside metal layer disposed between the plurality of semiconductor dies and the at least one heat dissipation element and a solder layer disposed between the backside metal layer and the at least one heat dissipation element. In some embodiments, the backside metal layer is in contact with the plurality of semiconductor dies and the first encapsulant. In some embodiments, the backside metal layer covers the plurality of semiconductor dies and the first encapsulant. In some embodiments, an area of the at least one heat dissipation element is smaller than an area of the backside metal layer. In some embodiments, an area of the solder layer is equal to the area of the at least one heat dissipation element. In some embodiments, a top surface of the at least one heat dissipation element is level with a top surface of the second encapsulant. In some embodiments, a thickness of the at least one heat dissipation element is 50 μm to 500 μm.

In accordance with some embodiments of the present disclosure, a semiconductor package includes an interposer substrate, a plurality of semiconductor dies, a first encapsulant, at least one metal bulk and a second encapsulant. The plurality of semiconductor dies are disposed on the interposer substrate. The first encapsulant is disposed on the interposer substrate and surrounds the plurality of semiconductor dies. The at least one metal bulk is disposed on the plurality of semiconductor dies. The second encapsulant is disposed on the first encapsulant and surrounds the at least one metal bulk, wherein an outer edge of the second encapsulant is aligned with an outer edge of the first encapsulant. In some embodiments, rear surfaces of the plurality of semiconductor dies are level with a top surface of the first encapsulant. In some embodiments, a top surface of the at least one metal bulk is level with a top surface of the second encapsulant. In some embodiments, the semiconductor package further includes a backside metal layer disposed between the plurality of semiconductor dies and the at least one metal bulk and a solder layer disposed between the backside metal layer and the at least one metal bulk. In some embodiments, an edge of the backside metal layer is aligned with the outer edge of the second encapsulant and the outer edge of the first encapsulant.

In accordance with alternative embodiments of the present disclosure, a manufacturing method of a semiconductor package includes: bonding a plurality of semiconductor dies on an interposer substrate; forming a first encapsulant on the interposer substrate and surrounding the plurality of semiconductor dies; bonding at least one heat dissipation element on the plurality of semiconductor dies; forming a second encapsulant on the first encapsulant, wherein the second encapsulant surrounds the at least one heat dissipation element and overlaps the first encapsulant; and performing a singulation process to cut the second encapsulant, the first encapsulant and the interposer substrate. In some embodiments, the manufacturing method of the semiconductor package further includes: forming a backside metal layer on the plurality of semiconductor dies and the first encapsulant before bonding the at least one heat dissipation element, and wherein bonding the at least one heat dissipation element on the plurality of semiconductor dies includes: bonding the at least one heat dissipation element on the backside metal layer through a solder layer. In some embodiments, the singulation process also cuts the backside metal layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
an interposer substrate;
a plurality of semiconductor dies disposed on the interposer substrate;
a first encapsulant disposed on the interposer substrate and surrounding the plurality of semiconductor dies;
at least one heat dissipation element disposed on the plurality of semiconductor dies; and
a second encapsulant disposed on the first encapsulant and surrounding the at least one heat dissipation element.

2. The semiconductor package according to claim 1, wherein the second encapsulant overlaps the first encapsulant.

3. The semiconductor package according to claim 1, wherein the number of the at least one heat dissipation element is one or more, and each heat dissipation element covers one or more semiconductor dies among the plurality of semiconductor dies.

4. The semiconductor package according to claim 1, wherein rear surfaces of the plurality of semiconductor dies are level with a top surface of the first encapsulant.

5. The semiconductor package according to claim 1, wherein a material of the at least one heat dissipation element comprises metal, metal alloy or a combination thereof.

6. The semiconductor package according to claim 5, further comprising:
a backside metal layer disposed between the plurality of semiconductor dies and the at least one heat dissipation element; and
a solder layer disposed between the backside metal layer and the at least one heat dissipation element.

7. The semiconductor package according to claim 6, wherein the backside metal layer is in contact with the plurality of semiconductor dies and the first encapsulant.

8. The semiconductor package according to claim 6, wherein the backside metal layer covers the plurality of semiconductor dies and the first encapsulant.

9. The semiconductor package according to claim 6, wherein an area of the at least one heat dissipation element is smaller than an area of the backside metal layer.

10. The semiconductor package according to claim 9, wherein an area of the solder layer is equal to the area of the at least one heat dissipation element.

11. The semiconductor package according to claim 1, wherein a top surface of the at least one heat dissipation element is level with a top surface of the second encapsulant.

12. The semiconductor package according to claim 1, wherein a thickness of the at least one heat dissipation element is 50 μm to 500 μm.

13. A semiconductor package, comprising:
an interposer substrate;
a plurality of semiconductor dies disposed on the interposer substrate;
a first encapsulant disposed on the interposer substrate and surrounding the plurality of semiconductor dies;
at least one metal bulk disposed on the plurality of semiconductor dies; and
a second encapsulant disposed on the first encapsulant and surrounding the at least one metal bulk, wherein an outer edge of the second encapsulant is aligned with an outer edge of the first encapsulant.

14. The semiconductor package according to claim 13, wherein rear surfaces of the plurality of semiconductor dies are level with a top surface of the first encapsulant.

15. The semiconductor package according to claim 13, wherein a top surface of the at least one metal bulk is level with a top surface of the second encapsulant.

16. The semiconductor package according to claim 13, further comprising:
a backside metal layer disposed between the plurality of semiconductor dies and the at least one metal bulk; and
a solder layer disposed between the backside metal layer and the at least one metal bulk.

17. The semiconductor package according to claim 16, wherein an edge of the backside metal layer is aligned with the outer edge of the second encapsulant and the outer edge of the first encapsulant.

18. A manufacturing method of a semiconductor package, comprising:
bonding a plurality of semiconductor dies on an interposer substrate;
forming a first encapsulant on the interposer substrate and surrounding the plurality of semiconductor dies;
bonding at least one heat dissipation element on the plurality of semiconductor dies;
forming a second encapsulant on the first encapsulant, wherein the second encapsulant surrounds the at least one heat dissipation element and overlaps the first encapsulant; and
performing a singulation process to cut the second encapsulant, the first encapsulant and the interposer substrate.

19. The manufacturing method of the semiconductor package according to claim 18, further comprising:
forming a backside metal layer on the plurality of semiconductor dies and the first encapsulant before bonding the at least one heat dissipation element, and wherein bonding the at least one heat dissipation element on the plurality of semiconductor dies comprises:
bonding the at least one heat dissipation element on the backside metal layer through a solder layer.

20. The manufacturing method of the semiconductor package according to claim 19, wherein the singulation process also cuts the backside metal layer.
